(19) United States
(12) Patent Application Publication
(10) Pub. No.: US 2026/0151841 A1
(43) Pub. Date: Jun. 4, 2026

(54) BRAZED JOINTS AND METHODS THEREOF

(71) Applicant: Technetics Group LLC, Charlotte, NC (US)

(72) Inventors: Angus McFadden, Santa Clara, CA (US); Freek Smits, Santa Clara, CA (US); Jason Wright, Santa Clara, CA (US); Kevin Brown, Santa Clara, CA (US)

(21) Appl. No.: 19/402,434

(22) Filed: Nov. 26, 2025

Related U.S. Application Data
(60) Provisional application No. 63/726,443, filed on Nov. 29, 2024.

(51) Int. Cl. B23K 1/00; B23K 35/30; B23K 103/00; C23C 16/458

(52) U.S. Cl. CPC B23K 1/0008; B23K 35/3013; C23C 16/4583; B23K 2103/52

(57) ABSTRACT

A brazed joint for process chamber components is provided by the technology described in the present application. The brazed joint is configured to withstand temperatures of 1000° C. or more. The brazed joint is formed between the surfaces of two process chamber components by placing a braze material between the two process chamber components. The braze material is a titanium and gold, a titanium and silver, or a combination thereof alloy. The braze material can be used with ceramic to ceramic joints as well as ceramic to metal joints. The ceramic material may be silicon nitride.

### CROSS-REFERENCE TO RELATED PATENT APPLICATIONS

The present application claims priority to and the benefit of U.S. Provisional Patent Application Ser. No. 63/726,443, filed Nov. 29, 2024, the disclosure of which is incorporated herein as if set out in full for all purposes.

### BACKGROUND

The technology of the present application relates to brazed joints and, more particularly, Silicon Nitride (Si₃N₄ and SiN) brazed joints and a method thereof to withstand temperatures of greater than 1000° C.

Often materials are required to be joined to form a joint. A system may use brazed joints as a means of permanent joining two or more components, typically metal but other types of material may be joined using a brazing technique. The brazed joint is formed by providing a material, typically called a filler material, between the two or more components to be joined. Similar to the components, above, the filler material is often a metal. The filler material is heated and introduced between the components to be joined. The filler metal has a lower melting point than the base materials, allowing it to flow into the joint via capillary action without melting the base metals. Once cooled, the filler metal solidifies, forming a strong, durable bond. Brazing is commonly used in various industries, including aerospace, automotive, HVAC, and electronics, due to its ability to join dissimilar materials and create hermetically sealed joints.

A brazed joint typically has high strength and resistance to fracture, thermal stress, and mechanical stress. The brazed joint is often clean with minimal distortion, and the components do not need to be melted along with the filler material. Thus, the brazed joint is desirable because it is a precision process that results in a strong joint.

While a brazed joint is desirable due to its strength and high corrosion resistance, it is difficult to braze many ceramic materials. Also, when brazing ceramic materials, the components and filler material often have temperature constraints such that the brazed ceramic joint cannot be used in high temperature (greater than 1000° C.). For example, Silicon Nitride is a desirable material to use in, for example, process chambers. However, forming complex parts with Silicon Nitride using brazing is presently limited to applications of about 500 to 600° C. as the braze joint fails at higher temperatures. The braze joint in certain aspects fails above 500 to 600° C. because the metal filler material melts.

Thus, against this background, it would be desirable to develop a braze for a brazed ceramic joint, especially a SiN joint, and method for brazing the joint.

### SUMMARY

This Summary is provided to introduce a selection of concepts in a simplified form that are further described below in the Detailed Description. This Summary, and the foregoing Background, is not intended to identify key aspects or essential aspects of the claimed subject matter. Moreover, this Summary is not intended for use as an aid in determining the scope of the claimed subject matter.

In certain aspects, the technology provided herein comprises a braze material for a brazed joint useful in process chambers. The braze material is placed between, for example, a ceramic part and another part, which another part may be either a ceramic material or a metal material. The braze material is melted and cooled to form the brazed joint between the process chamber parts. The braze material in certain embodiment comprises a titanium and gold or a titanium and silver alloy.

These and other aspects of the present system and method will be apparent after consideration of the Detailed Description and Figures herein.

### BRIEF DESCRIPTION OF THE DRAWINGS

Non-limiting and non-exhaustive embodiments of the present invention, including the preferred embodiment, are described with reference to the following figures, wherein like reference numerals refer to like parts throughout the various views unless otherwise specified.

FIG. 1 depicts a perspective view of process chamber equipment formed using technology of the present application.

FIG. 2 depicts a schematic cross section of process chamber equipment formed using technology of the present application.

FIG. 3 depicts a brazed joint consistent with the technology of the present application.

### DETAILED DESCRIPTION

Embodiments are described more fully below with reference to the accompanying figures, which form a part hereof and show, by way of illustration, specific exemplary embodiments. These embodiments are disclosed in sufficient detail to enable those skilled in the art to practice the invention. However, embodiments may be implemented in many different forms and should not be construed as being limited to the embodiments set forth herein. The following detailed description is, therefore, not to be taken in a limiting sense. Moreover, the technology of the present application will be described with relation to exemplary embodiments. The word “exemplary” is used herein to mean “serving as an example, instance, or illustration.” Any embodiment described herein as “exemplary” is not necessarily to be construed as preferred or advantageous over other embodiments. Additionally, unless specifically identified otherwise, all embodiments described herein should be considered exemplary.

Ceramic material has many advantages for application in numerous industries, some of which are mentioned above. Semiconductor manufacturing uses ceramic material in process chambers. The process chamber processes workpieces in a harsh, often extremely high temperature, working environment that makes ceramics desirable. Also, for many semiconductor applications, the dielectric characteristics of ceramic material make the ceramic material beneficial.

Electrostatic chucks (ESC or eChucks) often hold workpieces in process chambers for processing. The ESC needs to withstand the harsh operating condition and provide a dielectric material such that electrodes can be used to provide a chucking force to hold the workpiece on the ESC during the process steps. Ceramics are often used for ESCs and other process chamber equipment. One particularly good ceramic is Silicon Nitride (SiN), which is capable of withstanding temperatures over 1000° C.

SiN is a ceramic that operates at high temperature, is sufficiently strong, sufficiently wear resistant, and sufficiently inert for use in process chambers. SiN can be made into both flat and complex shapes. Flat SiN shapes conventionally are made by using molds and sintering the sheet of material. More complex shapes require more complicated manufacturing techniques including using various gaseous chemical vapor processes, which are generally known in the art. Unfortunately, SiN parts are not often susceptible to forming components by forming a joint between a SiN component and another component that can operate at high temperatures in harsh environments, whether the another component is a ceramic, such as SiN or other ceramic, a metal, or the like. In certain instances, it would be desirable to form a precise, strong, joint between a SiN component and another component, which may be SiN component or some other material.

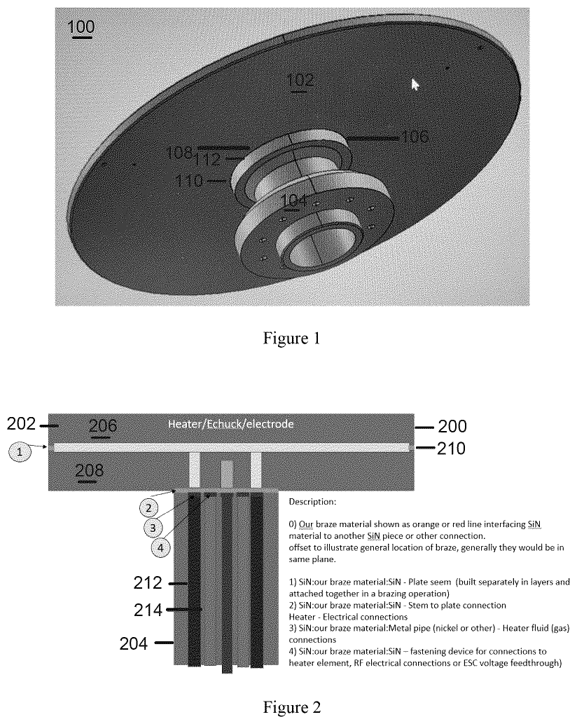

FIG. 1 shows an electrostatic chuck and pedestal assembly 100 for a process chamber. The assembly 100 includes an electrostatic chuck 102 and a pedestal 104. For exemplary purposes, the ESC 102 may be a SiN component formed by a sintering process whereas the pedestal 104 may be a SiN component formed using a gaseous chemical vapor process, however, either the components in other embodiments may comprise a plurality of components made only by a sintering process, a plurality of component made only by a gaseous chemical vapor process, or a plurality of components made by either a sintering process or a gaseous chemical vapor process. In yet other aspects, the components may be formed by other means. In certain embodiments, the pedestal may be a different type of ceramic or a metal.

The ESC 102 and the pedestal 104 are coupled to form a joint 106. The ESC 102 is a ceramic material, such as SiN. The pedestal 104 also may be formed from a ceramic material, such as SiN, but may also comprise a metal material. The joint 106 comprises a portion of a surface 108 of the ESC 102 and a portion of the surface 110 of the pedestal 104 with a filler material 112, also known as a braze 112. The braze 112, consistent with the technology described by the present application, comprises a titanium alloy. In certain embodiments, the titanium alloy is a combination of titanium and gold (TiAu), in other embodiments, the titanium alloy is a combination of titanium and silver (TiAg). In certain aspects, the titanium alloy comprises about 1 to 10% by weight titanium and, more preferably, about 2 to 6% by weight titanium and, even more preferably, between 3 and 5%, or about 4%, by weight titanium with the remainder of the alloy consisting essentially of silver and/or gold. For purposes of the present application, about is consistent with a tolerance for making titanium alloys or about means a tolerance of ±5%.

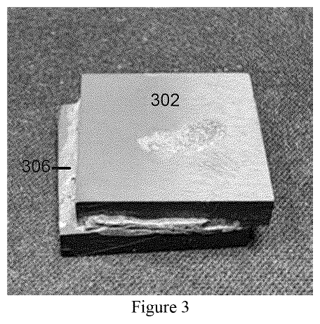

FIG. 2 shows a schematic cross section of a process chamber assembly 200, which is similar to the ESC and pedestal assembly 100 of FIG. 1. The process chamber assembly 200 includes workpiece platform 202 and a pedestal 204. The workpiece platform 202 may be an electrostatic chuck, a heater, or a combination of process chamber equipment. In certain embodiments, the workplace platform 202, which may be an ESC 202, comprises a first dielectric layer 206 coupled to a second dielectric layer 208 with a braze 210, which would fill a gap between the first dielectric layer 206 and the second dielectric layer 208, such as by capillary action or the like. The braze 210 fills the gap, such as by capillary action, as the coupling if formed by melting the braze 210 such that it can flow and bond to the first dielectric material and the second dielectric material. FIG. 3 shows a sample joint comprising a first SiN layer 302 coupled to a second SiN layer 304 by a braze 306, where the braze 306 is applied and melted at approximately 1850° F. to about 1870° F. over 20 to 30 minutes for a TiAg alloy comprising about 96% Ag and 4% Ti and meted at approximately 2050° F. to 2070° F. over about 20 to 30 minutes for a TiAu alloy comprising about 96% Au and 4% Ti, to identify but two exemplary brazed joints. The brazed joint 300 in FIG. 3 is similar to the SiN to SiN joint 1 shown in FIG. 2.

FIG. 2 also shows a series of different brazed joints at between the workpiece platform 202 and the pedestal 204. In this exemplary embodiment, the pedestal 204 is formed from SiN similar to the second dielectric layer 208. The braze 210 is applied to form brazed joint 2. The pedestal 204 also has a series of metal tubes 212 (or pipes 212) and a series of ceramic conduits 214 to facilitate connections, such as RF and electrical connections. The conduits may be formed from SiN. The braze 210 forms joints 3 and 4 coupling the workpiece platform 202 and the metal tubes 212 and ceramic conduits 214.

The braze 210 is described as being applied by melting the braze such that the braze travels through the gap via capillary action. The braze 210 is generally a bead or paste type material to allow for melting and flow. The braze 210, however, may also be formed into a tape material. The tape material would be applied to one or both surfaces to be joined and melted to form the brazed joint. In certain embodiments, tape material for the braze 210 is more effective.

Forming the brazed joint using the braze 210 to join SiN component to another material may be accomplished by the following steps. The steps below are exemplary, and may be performed in an order other than the steps discrete steps outlined here. Also, while shown as a number of discrete steps any particular step may be performed in multiple sub steps. In addition, steps shown may be combined into a single step. With that in mind, the technology of the present application may be performed by obtaining and cleaning the components to be joined. The components next are placed into a vacuum furnace and the vacuum furnace may be heated to an initial temperature to obtain a vacuum. For example, the over may be heated to about 1200° F. and held to reach a vacuum of 1×10⁻⁴ torr is reached. Once the required vacuum is achieved, the over is heated until just below the braze temperature to allow the entire assembly to reach a constant temperature, which for the TiAu may be approximately 1900° F. The furnace/oven is next heated to the braze melt temperature, such as for example, about 2060° F.±15 to 20° F., and held to allow the braze 210 to melt and flow to the surfaces of the multiple components, whether a bead, paste, tape, or the like. Once achieved, the furnace is cooled to a stabile temperature where the joint is formed and the joint is quenched to a safe temperature to be removed from the furnace/oven. Of course, for different braze material, the oven temperatures and pressures would be adjusted accordingly.

Although the technology has been described in language that is specific to certain structures, materials, and methodological steps, it is to be understood that the invention defined in the appended claims is not necessarily limited to the specific structures, materials, and/or steps described. Rather, the specific aspects and steps are described as forms of implementing the claimed invention. Since many embodiments of the invention can be practiced without departing from the spirit and scope of the invention, the invention resides in the claims hereinafter appended. Unless otherwise indicated, all numbers or expressions, such as those expressing dimensions, physical characteristics, etc. used in the specification (other than the claims) are understood as modified in all instances by the term “approximately.” At the very least, and not as an attempt to limit the application of the doctrine of equivalents to the claims, each numerical parameter recited in the specification or claims which is modified by the term “approximately” should at least be construed in light of the number of recited significant digits and by applying ordinary rounding techniques. Moreover, all ranges disclosed herein are to be understood to encompass and provide support for claims that recite any and all subranges or any and all individual values subsumed therein. For example, a stated range of 1 to 10 should be considered to include and provide support for claims that recite any and all subranges or individual values that are between and/or inclusive of the minimum value of 1 and the maximum value of 10; that is, all subranges beginning with a minimum value of 1 or more and ending with a maximum value of 10 or less (e.g., 5.5 to 10, 2.34 to 3.56, and so forth) or any values from 1 to 10 (e.g., 3, 5.8, 9.9994, and so forth).

What is claimed is:

1. An apparatus for a process chamber comprising:
a first component where the first component is a first ceramic material that is configured to operate at temperatures greater than 1000° C.;
a second component that is configured to operate at temperatures greater than 1000° C. spaced apart from the first component by a gap where the second component comprises a material selected from a group of materials consisting of: a second ceramic material, a metal material, or a combination thereof; and
a braze having a melting point lower than the first component and the second component in the gap, wherein the braze comprises a titanium alloy.

2. The apparatus of claim 1 wherein the first ceramic material is silicon nitride.

3. The apparatus of claim 2 wherein the second ceramic material is silicon nitride.

4. The apparatus of claim 2 wherein the titanium alloy comprises Titanium and gold (TiAu).

5. The apparatus of claim 4 wherein the titanium alloy comprises about 1% to 10% by weight titanium.

6. The apparatus of claim 4 wherein the titanium alloy comprises about 2% to 6% by weight titanium.

7. The apparatus of claim 4 wherein the titanium alloy comprises about 3% to 5% by weight titanium.

8. The apparatus of claim 4 wherein the titanium alloy comprises about 4% titanium.

9. The apparatus of claim 2 wherein the titanium alloy comprises titanium and silver (TiAg).

10. The apparatus of claim 9 wherein the titanium alloy comprises about 1% to 10% by weight titanium.

11. The apparatus of claim 9 wherein the titanium alloy comprises about 2% to 6% by weight titanium.

12. The apparatus of claim 9 wherein the titanium alloy comprises about 3% to 5% by weight titanium.

13. The apparatus of claim 9 wherein the titanium alloy comprises about 4% by weight titanium.

14. The apparatus of claim 1 wherein the first component is an electrostatic chuck and the second component is a pedestal.

15. An electrostatic chuck and pedestal assembly for a deposition process chamber comprising:
an electrostatic chuck formed from at least one ceramic dielectric material;
a pedestal formed from at least a second material and having a pedestal surface separated from an electrostatic chuck surface by a gap, wherein the second material is selected from a group of materials consisting of: a ceramic material, a metal material, or a combination thereof; and
a braze having a melting point lower than the first component and the second component in the gap between the pedestal surface and the electrostatic chuck surface, wherein the braze is selected from a group of braze consisting of: titanium and gold, titanium and silver, or a combination thereof.

16. The electrostatic chuck and pedestal assembly of claim 15 wherein the braze comprises a tape.

17. The electrostatic chuck and pedestal assembly of claim 15 wherein the electrostatic chuck comprises at least two ceramic dielectric materials coupled by the braze.

18. A method of forming a brazed joint configured to withstand temperatures of 1000° C., the method comprising:
providing a first process chamber component formed, in part, by a ceramic material having a ceramic material surface and a second process chamber component having a second process chamber component surface separated from the ceramic material surface by a gap;
placing a braze material comprising an alloy selected from the group of alloys consisting of titanium and gold, titanium and silver, or a combination thereof in the gap;
melting the braze material until the braze material fills the gap; and
cooling the braze material such that the first process chamber component is coupled to the second process chamber component by a brazed joint.

19. The method of claim 18 wherein placing the braze material comprises placing a tape on a surface selected from a group of surfaces consisting of: the ceramic material surface, the second process chamber component surface, or a combination thereof.

20. The method of claim 18 wherein the second process chamber component comprises a ceramic.
